(19) United States
(12) Patent Application Publication
(10) Pub. No.: US 2025/0199722 A1
(43) Pub. Date: Jun. 19, 2025

(54) MEMORY CONTROLLER, CONTROL METHOD AND MEMORY DEVICE

(71) Applicant: CANON KABUSHIKI KAISHA, Tokyo (JP)

(72) Inventors: DAISUKE SHIRAISHI, Tokyo (JP); WATARU OCHIAI, Tokyo (JP)

(21) Appl. No.: 18/975,614

(22) Filed: Dec. 10, 2024

(30) Foreign Application Priority Data
Dec. 13, 2023 (JP) 2023-210282

(51) Int. Cl. G06F 3/06

(52) U.S. Cl. CPC G06F 3/0659; G06F 3/0613; G06F 3/0673

(57) ABSTRACT

A memory controller, that is connectable to a memory that includes a plurality of bank groups that each includes a plurality of banks, holds a plurality of access requests to the memory, generates read or write commands from each of the plurality of access requests such that banks of different bank groups are set as destinations of adjacent read or write commands, and issues a page control command for an access request that is selected from the plurality of access requests, wherein a page control command for an access request for which open or close states of pages of a plurality of banks that are set as destinations satisfy a predetermined condition is preferentially issued.

### BACKGROUND

### Field of the Disclosure

The present disclosure relates to a memory controller and a control method.

### Description of the Related Art

Commonly, DRAMs are used as main storage devices in computer systems. With the advancement in functionality and performance of computer systems, there is increasing demand for DRAM performance, and various techniques of memory controllers have been proposed in order to more effectively achieve the performance.

Some DRAMs are configured to include a plurality of bank groups that each include a plurality of banks, and increase a data transfer speed through a prefetch operation being independently performed between bank groups. In a case where, in one of such DRAMs, a read command or a write command is issued to banks in the same bank group in a continuous manner, an interval between commands needs to meet the timing constraints for ensuring the completion of a prefetch of the previous command. For this reason, a gap occurs on a data bus, causing a decrease in the memory usage efficiency. Hereinafter, a read command and a write command are collectively referred to as “read or write commands”. In Japanese Patent Laid-Open No. 2021-157295, a decrease in the memory usage efficiency is suppressed by a memory controller issuing adjacent read or write commands obtained by dividing one memory access request, to banks of different bank groups.

Japanese Patent Laid-Open No. 2021-157295 does not mention page control that is performed when adjacent read or write commands obtained by dividing one memory access request are issued to banks of different bank groups. Even in a configuration where adjacent read or write commands are issued to banks of different bank groups, if an interval occurs between page control commands for a plurality of banks that are access destination of the adjacent read or write commands, a redundant gap occurs between the commands, and the memory usage efficiency decreases. According to an aspect of the present disclosure, such an issue is solved.

### SUMMARY

According to an aspect of the present disclosure, there is provided a memory controller that connectable to a memory that includes a plurality of bank groups that each includes a plurality of banks, the memory controller comprising: a holding circuit configured to hold a plurality of access requests in to the memory; a read and write control circuit configured to generate read or write commands from each of the plurality of access requests such that banks of different bank groups are set as destinations of adjacent read or write commands; and a page control circuit configured to issue a page control command for an access request that is selected from the plurality of access requests, wherein the page control circuit preferentially issues a page control command for an access request for which open or close states of pages of a plurality of banks that are set as destinations satisfy a predetermined condition.

Further features of various embodiments will become apparent from the following description of exemplary embodiments with reference to the attached drawings.

### BRIEF DESCRIPTION OF THE DRAWINGS

FIG. 1 is a block diagram showing a configuration example of a memory controller according to a first embodiment.

FIG. 2A is a diagram showing an exemplary data configuration of an entry to an access holding circuit.

FIG. 2B is a diagram showing an exemplary data configuration of an entry control signal.

FIG. 3 is a diagram showing a memory map according to the first embodiment.

FIG. 4 is a block diagram showing a configuration example of a page control circuit according to the first embodiment.

FIG. 5 is a flowchart showing generation processing of an ACT command issuing request according to the first embodiment.

FIG. 6 is a flowchart showing generation processing of a PRE command issuing request according to the first embodiment.

FIG. 7 is a block diagram showing a configuration example of a memory controller according to a second embodiment.

FIG. 8 is a block diagram showing a configuration example of a read and write control circuit according to the second embodiment.

FIG. 9 is a flowchart showing determination processing of a priority access type according to the second embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but limitation is not made to an embodiment that requires all such features, and multiple such features may be combined as appropriate. Furthermore, in the attached drawings, the same reference numerals are given to the same or similar configurations, and redundant description thereof is omitted.

### First Embodiment

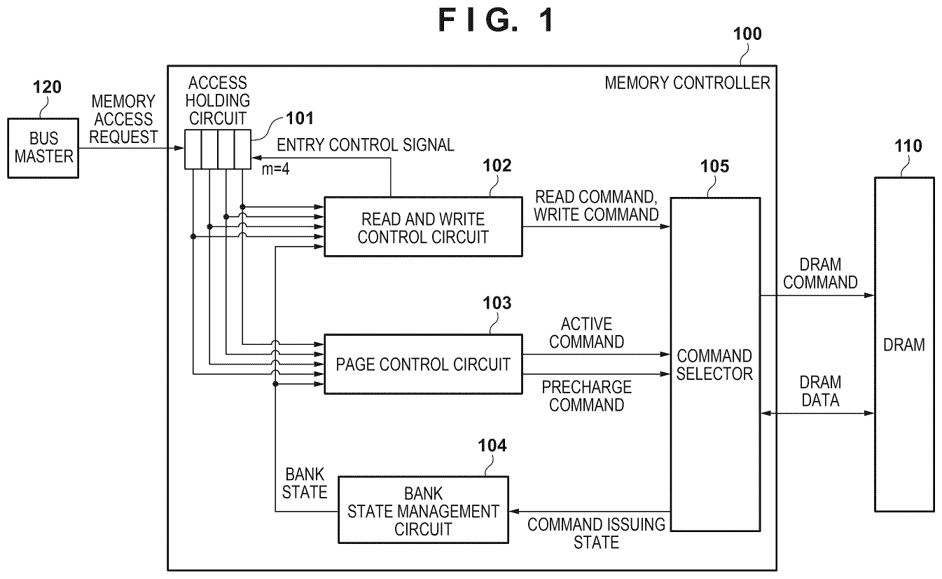

FIG. 1 is a block diagram showing a configuration example of a memory controller 100 according to a first embodiment. The memory controller 100 is connected to a DRAM 110 and a bus master 120, selects any suitable memory access request from a plurality of memory access requests, and issues a command. The DRAM 110 is a memory that includes a plurality of bank groups that each include a plurality of banks, and, in the present embodiment, a description will be given in which the DRAM 110 is configured to have four bank groups that each include four banks. However, in the present disclosure, the number of bank groups and the number of banks in each bank group are not limited, and it is sufficient that the number of bank groups is two or more, and the number of banks in each bank group is one or more. The bus master 120 transmits a memory access request that includes address information (in a case of a write command, write data is also included) to the memory controller 100. The memory controller 100 generates a DRAM command that includes a read or write command and a page control command based on the memory access request received from the bus master 120, and transmits the generated DRAM command to the DRAM 110. In addition, the memory controller 100 transmits/receives data to/from the DRAM 110 based on the transmitted DRAM command.

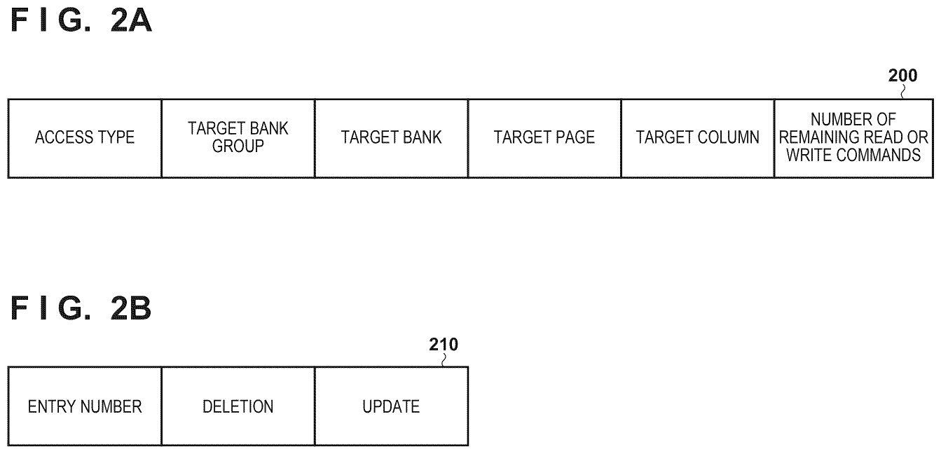

Next, a configuration of the memory controller 100 will be described. An access holding circuit 101 is a buffer for holding a plurality of memory access requests from the bus master 120. The access holding circuit 101 according to the present embodiment can hold m pieces (m≥2) of entry data. In this example, a description will be given in which m=4, but the present disclosure does not limit the value of m. FIG. 2A is a diagram showing an exemplary data configuration of entry data 200 held in the access holding circuit 101. At most, m pieces of the entry data 200 shown in FIG. 2A can be held in the access holding circuit 101. As shown in FIG. 2A, the entry data 200 has fields for access type, target bank group, target bank, target page, target column, and the number of remaining read or write commands. The access holding circuit 101 converts a memory access request received from the bus master 120, in correspondence with the fields of the entry data 200, and holds the resultant data. Information stored in the fields is as follows.

### (a) Access Type Field

The access type of the memory access request stored as the entry.
WRITE: the memory access request is a request to write (data)
READ: the memory access request is a request to read (data)

### (b) Target Bank Group Field

The bank group address that is accessed in accordance with the memory access request stored as the entry.

### (c) Target Bank Field

The bank address that is accessed in accordance with the memory access request stored as the entry.

### (d) Target Page Field

The page address that is accessed in accordance with the memory access request stored as the entry.

### (e) Target Column Field

The starting column address that is accessed in accordance with the memory access request stored as the entry.

### (f) The Number of Remaining Read-or-Write Command Field

The number of remaining DRAM read or write commands that are to be executed in accordance with the memory access request stored as the entry.

The access holding circuit 101 holds entry data while maintaining the order in which memory access requests were received from the bus master. When a memory access request is newly stored in the access holding circuit 101, the access holding circuit 101 stores corresponding entry data from the top entry in order. In addition, when one piece of entry data is deleted, the access holding circuit 101 shifts entry data of memory access information received later than the deleted entry data, to the top side. The access holding circuit 101 then stores a new memory access request from the bus master 120, as an entry subsequent to the last of the stored memory access requests. In this manner, entries are held in the access holding circuit 101 and are arranged in the order the entries were held. On the other hand, when a read and write control circuit 102 and a page control circuit 103 read out memory access requests from the access holding circuit 101, the memory access requests can be read out from any entry.

Next, an entry control signal that is input to the access holding circuit 101 will be described. FIG. 2B is a diagram showing an exemplary data configuration of an entry control signal 210. The entry control signal 210 includes an entry number field, a deletion field, and an update field. In a case where “1” is set in the deletion field of the entry control signal 210, the access holding circuit 101 deletes an entry indicated by the data in the entry number field. When “1” is set in the update field, the access holding circuit 101 updates the target bank group field and the target column field of an entry indicated by the data in the entry number field, to the bank group address and the top column address of the next read or write command. In addition, at this time, the access holding circuit 101 updates the number of remaining read-or-write command field to a value obtained by subtracting one from the value in the number of remaining read-or-write command field.

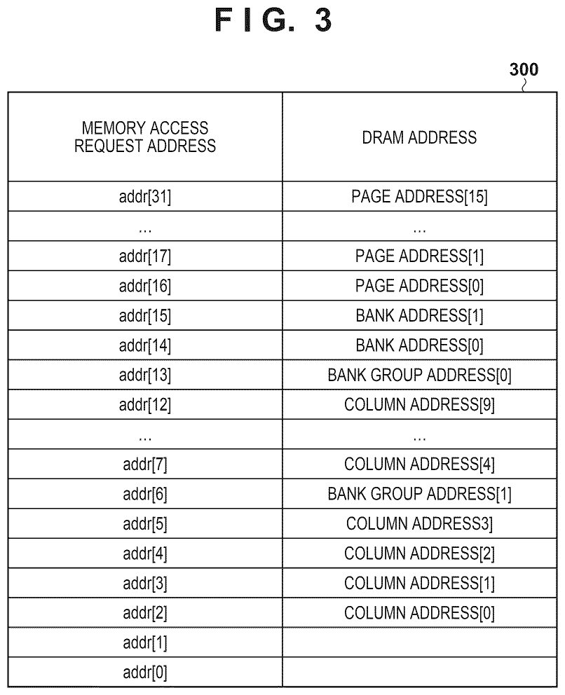

The bank group address and the top column address of a read or write command are calculated based on address information of the entry and the memory map 300 shown in FIG. 3. The memory map 300 according to the present embodiment envisions a case where DRAM data has a 32-bit width, and the burst length of a read or write command is 16. In addition, it is envisioned that the data width of a memory access request is 8 bits/address, and thus four addresses represented by the lower 2 bits of the memory access request address (addr (0) and addr (1)) are not allocated to DRAM addresses. In order to realize a burst length of 16 with a 32-bit width, 32 addresses (column addresses (0) to (3)) are accessed in a single read or write access. The bank group address (1) is allocated to the bits immediately above the column address (3), and thus, in adjacent read or write commands, the first bit of the bank group address toggles. As a result, read or write commands are issued to different bank groups. Note that the present disclosure does not depend on the memory map 300 shown in FIG. 3, and any memory map in which adjacent read or write commands correspond to different bank group addresses may be used.

The read and write control circuit 102 can reference all of the memory access requests stored in the access holding circuit 101. The read and write control circuit 102 selects any suitable memory access request from memory access requests according to which a page to be accessed is open, from among the memory access requests stored in the access holding circuit 101. Determination is performed on whether or not a page that is accessed in accordance with a memory access request is open, based on the target bank group field, the target bank field, and the target page field of the entry data 200, and a bank state that is generated by a bank state management circuit 104. The read and write control circuit 102 generates a read or write command from the selected memory access request, and outputs the command to a command selector 105.

Next, a procedure in which the read and write control circuit 102 generates an entry control signal will be described. When the last read or write command that is executed for one memory access request is issued, processing of the memory access request is complete. In this case, the read and write control circuit 102 generates an entry control signal (in which the deletion field is set to “1”) instructing that an entry corresponding to the memory access request be deleted from the access holding circuit 101. On the other hand, in a case where a read or write command that is not the last read or write command in a memory access request is issued, the read and write control circuit 102 generates an entry control signal so as to update the entry corresponding to the memory access request of the access holding circuit 101. Note that, in a case where the last read or write command is issued, the corresponding entry is deleted, and thus there is no need to update the entry. In addition, whether or not a read command or write command that has been issued is the last command can be determined based on whether or not the number of remaining read-or-write command field of the entry data 200 is “1”.

The page control circuit 103 can reference all of the memory access requests stored in the access holding circuit 101. The page control circuit 103 generates page control commands such as an active command and a precharge command based on a memory access request held in the access holding circuit 101 and a bank state that is output by the bank state management circuit 104. The generated page control command is output to the command selector 105. Hereinafter, the active command is referred to as an “ACT command”, and the precharge command is referred to as a “PRE command”.

The bank state management circuit 104 updates a bank state based on a command issuing state that is input from the command selector 105. The command issuing state is made up of the type of a command (read or write) issued to the DRAM 110 by the command selector 105, and a bank group, a bank, and a page for which the command was issued. The bank state includes information indicating whether or not the page is open for each of the banks that make up the DRAM 110, and the address of a page that is open.

The command selector 105 selects one command from a read or write command input from the read and write control circuit 102 and an ACT command and a PRE command input from the page control circuit 103, and issues the command to the DRAM 110. Note that a command such as a refresh command or the like may also be selected at the same time, which is not described in the present embodiment. In addition, the command selector 105 generates information regarding a command issuing state from the command type of the command issued to the DRAM 110, and the bank group, the bank, and the page for which the command was issued, and outputs the information to the bank state management circuit 104.

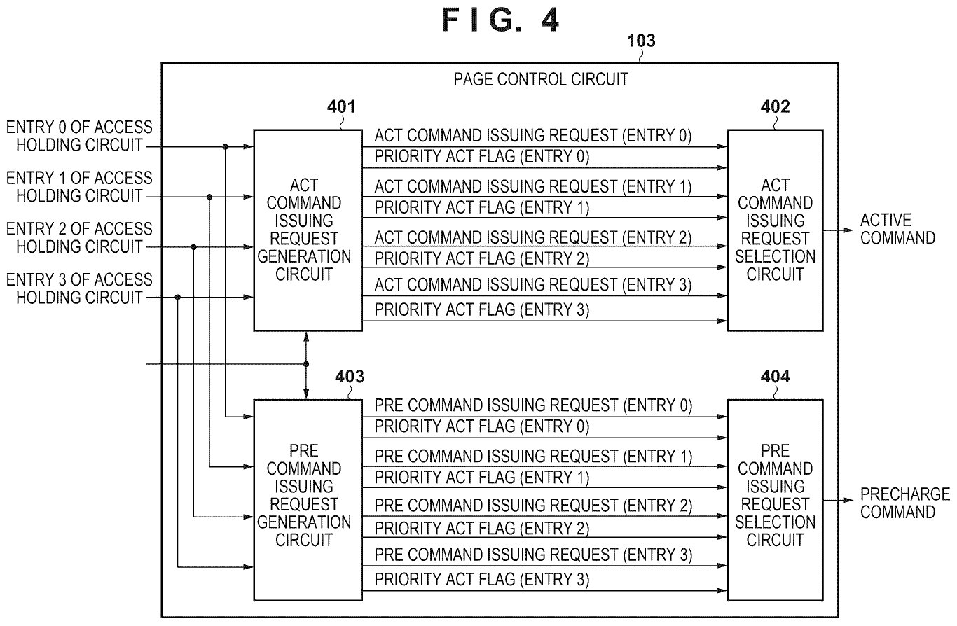

FIG. 4 is a block diagram showing a configuration example of the page control circuit 103 according to the first embodiment. The page control circuit 103 includes an ACT command issuing request generation circuit (hereinafter, an ACT request generation circuit 401) and an ACT command issuing request selection circuit (hereinafter, an ACT request selection circuit 402). In addition, the page control circuit 103 includes a PRE command issuing request generation circuit (hereinafter, a PRE request generation circuit 403) and a PRE command issuing request selection circuit (hereinafter, a PRE request selection circuit 404).

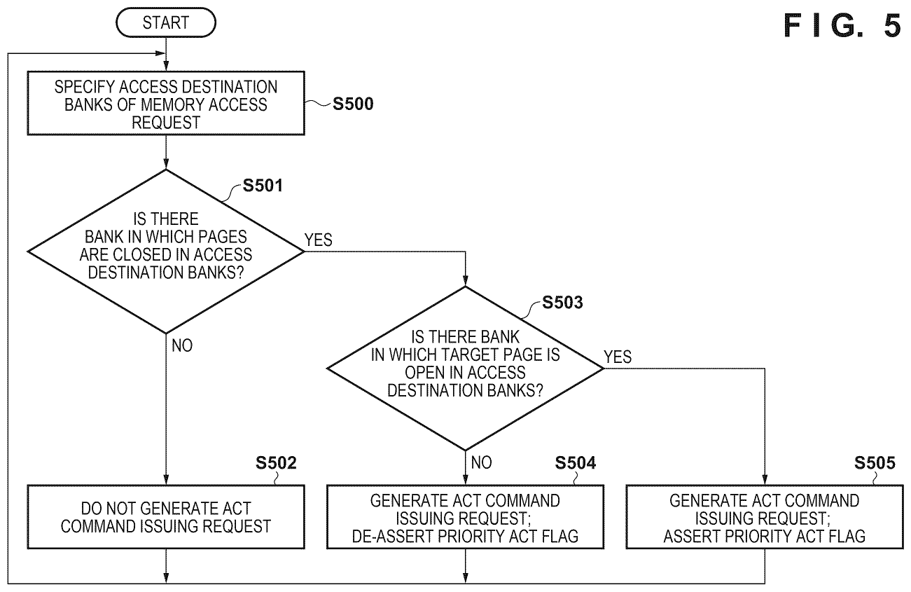

A page control command (ACT command) for a memory access request in which the open or close states of the pages of a plurality of banks that are set as destinations satisfy a predetermined condition is preferentially issued by the ACT request generation circuit 401 and the ACT request selection circuit 402. The ACT request generation circuit 401 generates an ACT command issuing request based on the bank states provided from the bank state management circuit 104, for each of the memory access requests held in the access holding circuit 101. In addition, the ACT request generation circuit 401 determines whether or not the generated ACT command issuing request is to be preferentially selected by the ACT request selection circuit 402, based on the states of banks that are set as destinations of the memory access request, and generates a priority ACT flag indicating the determination result. FIG. 5 is a flowchart showing generation processing of an ACT command issuing request according to the present embodiment. Operations of the ACT request generation circuit 401 will be described below in more detail with reference to the flowchart in FIG. 5. Generation processing of an ACT command issuing request is executed for each of the memory access requests held in the access holding circuit 101, for each cycle of memory access.

The ACT request generation circuit 401 specifies access destination banks of a memory access request based on the target bank group and the target bank of the memory access request, the number of remaining read or write commands, and the number n of banks that are sequentially accessed in accordance with the memory access request (step S500). In the memory map 300 (FIG. 3) in the present embodiment, n=2 since the memory access request alternatingly accesses two banks that belong to different bank groups. Thus, for example, if the target bank group is “0”, the target bank is “0”, and the number of remaining read or write commands is two or more, two banks represented by (bank group address, bank address), namely (0, 0) and (2, 0) are access destination banks. Note that, in the present embodiment, n=2, but there is no limitation thereto. That is to say, n does not limit the number of bank groups and the number of banks in each bank group, and it suffices for n to be two or larger and smaller than or equal to the number of bank groups, and a power of 2.

Next, the ACT request generation circuit 401 determines whether or not n access destination banks include a bank in a state where all the pages are closed (step S501). If it is determined that there is no access destination bank in a state where all the pages are closed (NO in step S501), the ACT request generation circuit 401 does not generate an ACT command issuing request (step S502). On the other hand, if it is determined that there is an access destination bank in a state where all the pages are closed (YES in step S501), the ACT request generation circuit 401 determines whether or not the access destination banks include a bank in which the target page is open (step S503).

If it is determined that the access destination banks do not include an access destination bank in which the target page is open (NO in step S503), the ACT request generation circuit 401 generates an ACT command issuing request to the access destination bank in a state where all of the pages are closed (step S504). In this case, the access destination banks do not include a bank in which the target page is open, and thus, even if issuance of an ACT command is delayed, a redundant gap does not occur between read or write commands. Therefore, the ACT request generation circuit 401 de-asserts a priority ACT flag related to the ACT command issuing request that is generated, in order to perform notification that the ACT request selection circuit 402 does not need to give priority to this ACT command (step S504). On the other hand, if it is determined that there is an access destination bank in which the target page is open (YES in step S503), the ACT request generation circuit 401 generates an ACT command issuing request to the access destination bank in a state where all of the pages are closed (step S505). In this case, the access destination banks include a bank in a state where an ACT command can be issued (bank in which all of the pages are closed) and a bank in a state where an ACT command does not need to be issued (bank in which the target page is open). The ACT request generation circuit 401 generates an ACT command issuing request to a bank in a state where an ACT command can be issued. In addition, in this manner, if the access destination banks include a bank in which the target page is open and a bank in which the target page is not open, and issuance of an ACT command to the bank in which the target page is not open is delayed, a redundant gap occurs between read or write commands. For this reason, the ACT request generation circuit 401 asserts a priority ACT flag related to the ACT command issuing request that is generated, in order to perform notification that the ACT request selection circuit 402 gives priority to issuance of the ACT command (step S505).

Note that, when an ACT command issuing request is generated in steps S504 and S505, there may be a plurality of access destination banks in a state where all of the pages are closed. In such a case, the ACT request generation circuit 401 generates an ACT command issuing request to a bank that is accessed first among the plurality of access destination banks. The bank that is accessed first can be determined based the target bank group and the target bank of the entry data 200, for example. More specifically, the bank that is accessed first is determined based on the order of change of access destination banks that is indicated by the target bank group and the target bank of the entry data 200 when the number of memory access request addresses sequentially increases. In the present embodiment, for example, n=2, and the bank group address (1) is used in order to alternatingly access bank groups. Therefore, for example, in a case where the target bank group of the entry data 200 is “10” and the target bank is “11”, a bank that is accessed first is specified in accordance with the following (1) and (2) in this order.
(1) bank “11” of bank group “10”
(2) bank “11” of bank group “00”

The ACT request selection circuit 402 selects one ACT command issuing request from ACT command issuing requests generated by the ACT request generation circuit 401, and outputs the selected ACT command issuing request as an ACT command to the command selector 105. In case where a plurality of ACT command issuing requests are generated at the same time, the ACT request selection circuit 402 preferentially selects an ACT command issuing request for which the priority ACT flag has been asserted. If there are a plurality of ACT command issuing requests for which the priority ACT flag has been asserted, the ACT request selection circuit 402 selects an ACT command issuing request to the memory access request that was held in the access holding circuit 101 first, from the plurality of ACT command issuing requests. As described above, entries are held in the access holding circuit 101 in the order the entries were held, and it is possible to easily determine a memory access request that was held first.

With the above-described ACT command issuance control that is performed by the ACT request generation circuit 401 and the ACT request selection circuit 402, ACT commands for one memory access request are issued in a concentrated manner. In a case where the number of banks that are sequentially accessed in accordance with a memory access request is two, for example, there is a need to issue two ACT commands to two different bank groups. With the above-described ACT command issuance control, an ACT command is kept from being issued to another bank group between issuance of a first ACT command and issuance of a second ACT command in response to a memory access request. Thus, it is possible to suppress the occurrence of a redundant gap due to an interval occurring between the first ACT command and the second ACT command, and the memory usage efficiency improves.

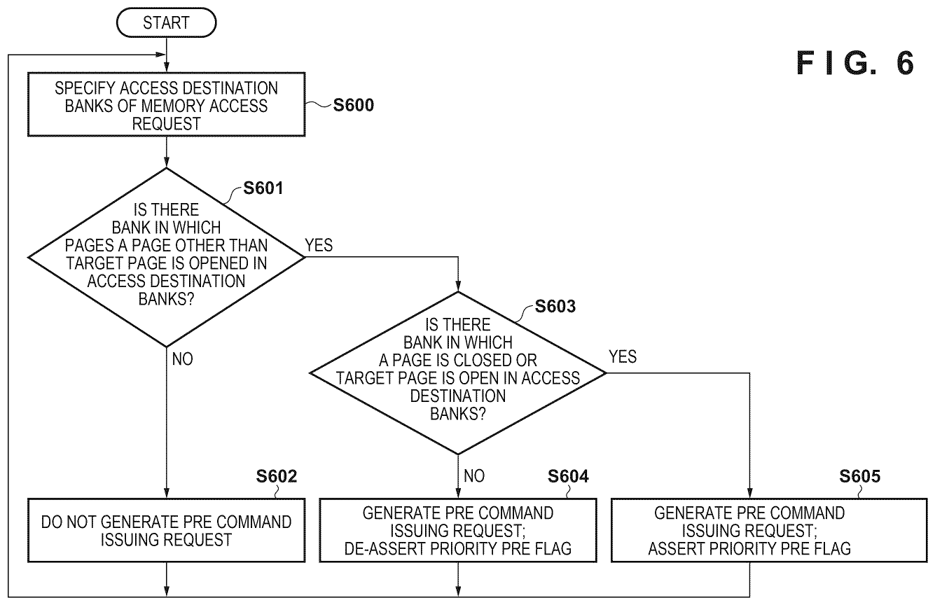

In addition, a page control command (PRE command) for a memory access request in which the open or close states of pages of a plurality of destination banks satisfy a predetermined condition is preferentially issued by the PRE request generation circuit 403 and the PRE request selection circuit 404. The PRE request generation circuit 403 generates a PRE command issuing request for each of the memory access requests held in the access holding circuit 101, based on the bank states provided from the bank state management circuit 104. In addition, the PRE request generation circuit 403 determines whether or not the generated PRE command issuing request is to be preferentially selected by the PRE request selection circuit 404, based on the bank states of destinations of the memory access request, and generates a priority PRE flag indicating the determination result. FIG. 6 is a flowchart showing generation processing of a PRE command issuing request according to the present embodiment. Operations of the PRE request generation circuit 403 will be described below in detail with reference to the flowchart in FIG. 6. Note that generation processing of a PRE command issuing request is executed for each of the memory access requests held in the access holding circuit 101, for each cycle of memory access.

The PRE request generation circuit 403 specifies an access destination bank of a memory access request based on the target bank group and the target bank of the memory access request, the number of remaining read or write commands, and the number n of banks that are sequentially accessed in accordance with the memory access request (step S600). A method for specifying an access destination bank is the same as the above generation processing of an ACT command issuing request (FIG. 5).

The PRE request generation circuit 403 determines whether or not access destination banks include a bank in which a page other than the target page is open (step S601). If it is determined that there is no access destination bank in which a page other than the target page is open (NO in step S601), the PRE request generation circuit 403 does not generate a PRE command issuing request (step S602). If it is determined that there is an access destination bank in which a page other than the target page is open (YES in step S602), the PRE request generation circuit 403 determines whether or not there is an access destination bank in a state where all of the pages are closed or there is an access destination bank in a state where the target page is open (step S603).

If it is determined that there is no access destination bank in which all of the pages are closed and there is no access destination bank in which the target page is open (NO in step S603), the PRE request generation circuit 403 generates a PRE command issuing request. In this case, even when issuance of a PRE command is delayed, no redundant gap occurs between read or write commands. For this reason, in order to perform notification that issuance of a PRE command does not need to be prioritized by the PRE request selection circuit 404, a priority PRE flag related to the PRE command issuing request is de-asserted (step S604). On the other hand, if there is an access destination bank in a state where all of the pages are closed or there is an access destination bank in a state where the target page is open (YES in step S603), the PRE request generation circuit 403 generates a PRE command issuing request (step S605). In this case, the access destination banks include a bank for which a PRE command needs to be issued (bank in which a page other than the target page is open) and a bank for which a PRE command does not need to be issued (a bank in which all of the pages are closed and a bank in which the target page is open). The PRE request generation circuit 403 generates a PRE command issuing request to the bank for which a PRE command needs to be issued. In addition, in a case where the access destination banks include a bank that requires a PRE command and a bank that does not require a PRE command in this manner, and issuance of a PRE command to the bank that requires a PRE command is delayed, a redundant gap occurs between read or write commands. For this reason, the PRE request generation circuit 403 asserts a priority PRE flag related to the PRE command issuing request, in order to notify the PRE request selection circuit 404 that the PRE command issuing request is prioritized (step S605).

Note that, when a PRE command issuing request is generated in steps S604 and S605, and pages other than the target pages are open in a plurality of banks among the access destination banks, a PRE command issuing request to a bank that is accessed first among these banks is generated. The description of steps S504 and S505 applies to the bank that is accessed first.

The PRE request selection circuit 404 selects one PRE command issuing request from PRE command issuing requests generated by the PRE request generation circuit 403, and outputs the selected request as a PRE command to the command selector 105. When a plurality of PRE command issuing requests are generated at the same time, the PRE request selection circuit 404 preferentially selects a PRE command issuing request for which the priority PRE flag has been asserted. If there are a plurality of PRE command issuing requests for which the priority PRE flag has been asserted, the PRE request selection circuit 404 selects a PRE command issuing request to the memory access request that was stored in the access holding circuit 101 first, among the plurality of PRE command issuing requests.

With the above PRE command issuance control that is performed by the PRE request generation circuit 403 and the PRE request selection circuit 404, PRE commands required for issuing ACT commands for one memory access request are issued in a concentrated manner. In a case where the number of banks that are sequentially accessed in accordance with a memory access request is two, for example, two banks need to be brought into a closed state. With the above-described PRE command issuance control, PRE commands for bringing these two banks into a closed state are issued in a concentrated manner. As a result, a first ACT command and a second ACT command can be consecutively issued for a memory access request, and it is possible to suppress the occurrence of a redundant gap due to an interval occurring between these ACT commands, and the memory usage efficiency improves.

As described above, according to the first embodiment, in a case where adjacent read or write commands obtained by dividing one memory access request are issued to banks of different bank groups, page control of access destination banks of the read or write commands is executed in a concentrated manner. For this reason, it is possible to suppress a decrease in the memory usage efficiency.

### Second Embodiment

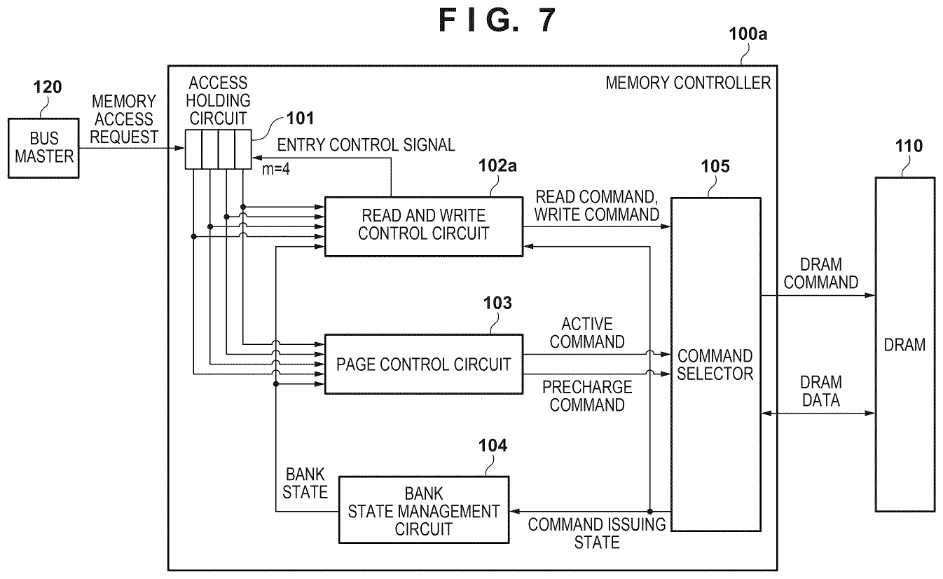

A second embodiment solves an issue of a decrease in the memory usage efficiency caused by selecting a memory access request to a bank group in which a prefetch is being executed, and thus putting issuance of a read or write command on hold. FIG. 7 is a block diagram showing a configuration example of a memory controller 100a according to the second embodiment. Constituent elements similar to those of the first embodiment/(FIG. 1) are given the same reference numerals. A read and write control circuit 102a according to the second embodiment determines whether or not a prefetch is being executed in each bank group, using a command issuing state that is input from the command selector 105, and operates such that a memory access request for which completion of a prefetch needs to be waited for is not selected. Accordingly, a situation is avoided where a memory access request to a bank group in which a prefetch is being executed is selected, and a decrease in the memory usage efficiency is prevented.

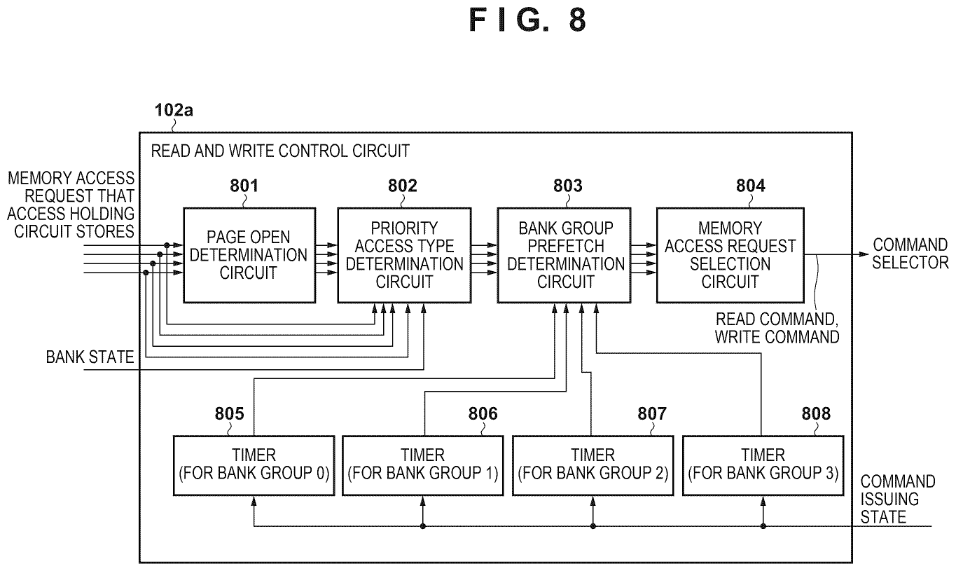

FIG. 8 is a block diagram showing a configuration example of the read and write control circuit 102a according to the second embodiment. The read and write control circuit 102a includes a page open determination circuit 801, a priority access type determination circuit 802, a bank group prefetch determination circuit (hereinafter, a prefetch determination circuit 803), a memory access request selection circuit 804, and timers 805 to 808. The timers 805 to 808 correspond to the bank groups 0 to 3 of the DRAM 110.

The page open determination circuit 801 determines, based on a bank state, whether or not the target page is open in the target bank of the target bank group, for each of the memory access requests stored in the access holding circuit 101. The page open determination circuit 801 then outputs only memory access requests for which the target page is open, from among the memory access requests stored in the access holding circuit 101, to the priority access type determination circuit 802, and masks the other memory access requests.

The priority access type determination circuit 802 determines whether or not the access type of each of the memory access requests output by the page open determination circuit 801 is a priority access type. The priority access type is generated by the priority access type determination circuit 802 based on the memory access requests stored in the access holding circuit 101 and the bank states, and indicates whether a read command or a write command is preferentially issued. The priority access type determination circuit 802 outputs only a memory access request corresponding to the priority access type, to the prefetch determination circuit 803, and masks the other memory access requests.

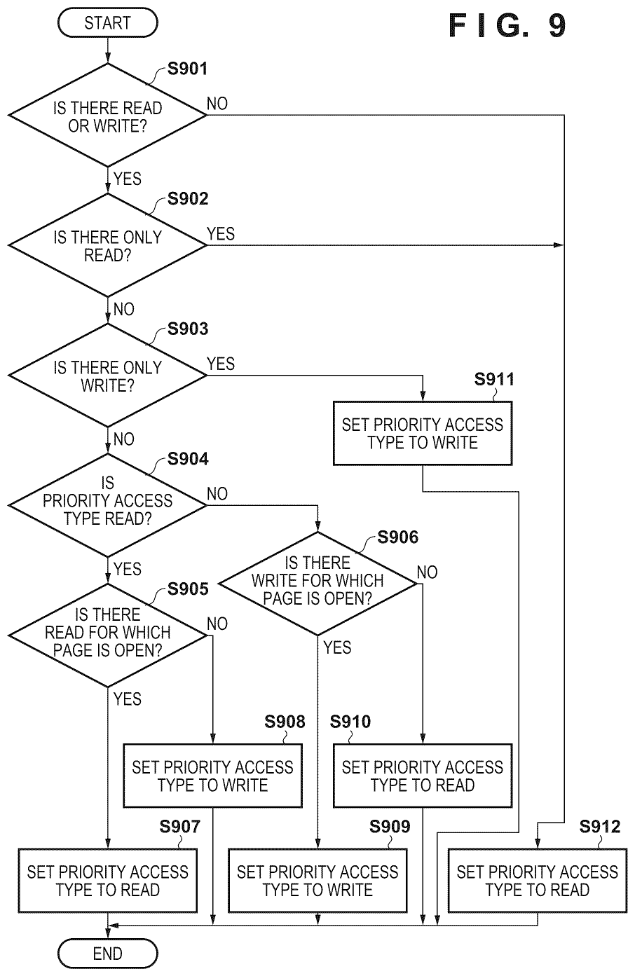

FIG. 9 is a flowchart showing an example of determination processing of a priority access type that is performed by the priority access type determination circuit 802. The priority access type determination circuit 802 determines a priority access type in accordance with this flowchart for each cycle. In addition, when the access holding circuit 101 has no memory access request, the priority access type is set to “read”.

In steps S901 to S903, the priority access type determination circuit 802 determines whether or not the access holding circuit 101 holds a memory access request for a read or write operation. If there is no memory access request for a read or write operation (NO in step S901), the priority access type determination circuit 802 sets the priority access type to “read” (step S912). In addition, also in a case where the access holding circuit 101 holds only a memory access request for a read operation (YES in steps S901 and S902), the priority access type determination circuit 802 sets the priority access type to “read” (step S912). On the other hand, when the access holding circuit 101 holds only a memory access request for a write operation (YES in step S903), the priority access type determination circuit 802 sets the priority access type to “write” (step S911).

If the access holding circuit 101 holds a memory access request for both read and write operations (NO in step S903), the priority access type determination circuit 802 determines whether the current priority access type is “read” or “write” (step S904). Note that the current priority access type is an access type (read or write) determined as being prioritized in the previous cycle. If the current priority access type is “read” (YES in step S904), determination is performed on whether or not there is a memory access request for which the direction is the same as that of the priority access type (here, “read”), and the target page has already been opened (step S905). On the other hand, if the priority access type is “write” (NO in step S904), determination is performed on whether or not there is a memory access request for which the direction is the same as that of the priority access type (here “write”), and the target page has been opened already (step S906). If there is such a memory access request (YES in step S905 or step S906), the priority access type is not changed (steps S907 and S909). On the other hand, if there is no such memory access request (NO in step S905 or S906), the priority access type is changed (steps S908 and S910). In this manner, a priority access type is determined.

If a command issuing state that is output from the command selector 105 indicates issuance of a read or write command to the bank group 0, the timer 805 sets a period during which a read or write command cannot be issued to the same bank group due to a prefetch operation. During a time other than the set time, the value of the timer 805 is decremented over time, and the timer 805 stops at 0. The timers 806 to 808 operate in a similar manner to the timer 805, with respect to the bank group 1 to 3 respectively corresponding thereto.

The prefetch determination circuit 803 determines whether or not there is a need to wait for a prefetch of the target bank group to be complete, for each of the memory access requests output by the priority access type determination circuit 802. Whether or not there is a need to wait for a prefetch of the target bank group to be complete is determined based on whether or not the values of the timers 805 to 808 corresponding to the target bank groups of the memory access requests are other than 0. The prefetch determination circuit 803 outputs only memory access requests for which there is no need to wait for completion of a prefetch of the target bank group, to the memory access request selection circuit 804, and masks memory access requests for which there is a need to wait for completion of a prefetch of the target bank group.

The memory access request selection circuit 804 selects any suitable memory access request from the memory access requests output by the prefetch determination circuit 803. A read command or a write command for the selected memory access request is then generated, and is output to the command selector 105.

As described above, according to the second embodiment, it is possible to suppress a decrease in the memory usage efficiency by not selecting a memory access request for which there is a need to wait for a prefetch of a bank group to be complete.

As described above, with the memory controller according to the present disclosure, in a case where adjacent read or write commands are issued from one memory access request to banks of different bank groups, page control of a destination banks of the read or write commands is executed in a concentrated manner. For this reason, a decrease in the memory usage efficiency of the DRAM is prevented. In addition, the memory controller according to the present disclosure can be used for various memory controllers that are connected to DRAMs, select any suitable memory access request from a plurality of memory access requests, and issue a command.

Some embodiments of the present disclosure are not limited to the above embodiments, and various changes and modifications can be made within the spirit and scope of the present disclosure. Therefore, to apprise the public of the scope of the present disclosure, the following claims are made.

### OTHER EMBODIMENTS

Embodiment(s) of the present disclosure can also be realized by a computer of a system or apparatus that reads out and executes computer-executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer-executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer-executable instructions. The computer-executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has described exemplary embodiments, it is to be understood that some embodiments are not limited to the disclosed exemplary embodiments. The scope of the following claims is to be accorded the broadest interpretation so as to encompass all such modifications and equivalent structures and functions.

This application claims priority to Japanese Patent Application No. 2023-210282, which was filed on Dec. 13, 2023 and which is hereby incorporated by reference herein in its entirety.

What is claimed is:

1. A memory controller that is connectable to a memory that includes a plurality of bank groups that each includes a plurality of banks, the memory controller comprising:
a holding circuit configured to hold a plurality of access requests to the memory;
a read and write control circuit configured to generate read or write commands from each of the plurality of access requests such that banks of different bank groups are set as destinations of adjacent read or write commands; and
a page control circuit configured to issue a page control command for an access request that is selected from the plurality of access requests, wherein the page control circuit preferentially issues a page control command for an access request for which open or close states of pages of a plurality of banks that are set as destinations satisfy a predetermined condition.

2. The memory controller according to claim 1, wherein
the page control circuit preferentially issues a page control command for an access request that includes, as destinations, a bank in a state where the page control command can be issued and a bank in a state where the page control command does not need to be issued.

3. The memory controller according to claim 2, wherein
the page control command is an active command,
the bank in a state where the page control command can be issued is a bank in which all pages are closed, and
the bank in a state where the page control command does not need to be issued is a bank in which a target page of a read or write command that is generated from an access request is open.

4. The memory controller according to claim 1, wherein
the page control circuit preferentially issues a page control command for an access request that includes, as destinations, a bank in a state where the page control command needs to be issued and a bank in a state where the page control command does not need to be issued.

5. The memory controller according to claim 4, wherein
the page control command is a precharge command,
the bank in a state where the page control command needs to be issued is a bank in which a page different from a target page of a read or write command that is generated from an access request is open, and
the bank in a state where the page control command does not need to be issued is a bank in which a page different from a target page is not open.

6. The memory controller according to claim 1, wherein
in a case where there is a plurality of page control commands generated from one access request for which states of a plurality of destination banks satisfy the predetermined condition, the page control circuit preferentially issues a page control command to a bank that is accessed first from among the plurality of banks.

7. The memory controller according to claim 1, wherein
in a case where there are two or more access requests in which states of a plurality of destination banks satisfy the predetermined condition, the page control circuit preferentially issues a page control command that is generated from an access request that was held in the holding circuit first, from among the plurality of access requests.

8. The memory controller according to claim 1, wherein
the read and write control circuit generates a read or write command for an access request that is selected from remaining access requests obtained by removing an access request that includes, as a destination, a bank group in which a prefetch is being executed, from the plurality of access requests.

9. The memory controller according to claim 1, wherein
the read and write control circuit determines whether a read command or a write command is preferentially issued, based on access types of the plurality of access requests and states of destination banks of the plurality of access requests.

10. A control method of a memory controller that is connectable to a memory that includes a plurality of bank groups that each includes a plurality of banks, the control method comprising:
holding a plurality of access requests to the memory in a holding circuit,
executing read and write control for generating read or write commands from each of the plurality of access requests such that banks of different bank groups are set as destinations of adjacent read or write commands; and
executing page control for issuing a page control command for an access request that is selected from the plurality of access requests, wherein in the page control, a page control command for an access request for which open or close states of pages of a plurality of banks that are set as destinations satisfy a predetermined condition is preferentially issued.

11. A memory device comprising:
a memory that includes a plurality of bank groups that each includes a plurality of banks; and
a controller that is connectable to the memory, wherein the controller includes:
a holding circuit configured to hold a plurality of access requests to the memory;
a read and write control circuit configured to generate read or write commands from each of the plurality of access requests such that banks of different bank groups are set as destinations of adjacent read or write commands; and
a page control circuit configured to issue a page control command for an access request that is selected from the plurality of access requests, wherein
the page control circuit preferentially issues a page control command for an access request for which open or close states of pages of a plurality of banks that are set as destinations satisfy a predetermined condition.
